(19) United States
(12) Patent Application Publication
(10) Pub. No.: US 2012/0235124 A1
(43) Pub. Date: Sep. 20, 2012

(54) Organic Optoelectronic Device and Method

(75) Inventor: Adam Strevens, Cambridge (GB)

(73) Assignee: Cambridge Display Technology Limited, Cambridgeshire (GB)

(21) Appl. No.: 13/390,251

(22) PCT Filed: Nov. 10, 2010
(86) PCT No.: PCT/GB2010/002065

§ 371 Date: May 3, 2012

(30) Foreign Application Priority Data
Nov. 10, 2009 (GB) 0919648.6

(51) Int. Cl. H01L 51/54; H01L 51/40

(52) U.S. Cl. 257/40; 438/46; 257/E51.026

(57) ABSTRACT

An organic optoelectronic device, such as an organic light emitting device, includes an anode, a cathode and an active organic layer between the anode and the cathode. The cathode includes a layer including a complex salt, a first conductive layer, and a second conductive layer over the first conductive layer, and provides a stable device.

This invention relates to organic optoelectronic devices, in particular an organic light emitting devices, and methods of making the same.

Electronic devices comprising active organic materials are attracting increasing attention for use in devices such as organic light emitting diodes, organic photovoltaic devices, organic photosensors, organic transistors and memory array devices. Devices comprising organic materials offer benefits such as low weight, low power consumption and flexibility. Moreover, use of soluble organic materials allows use of solution processing in device manufacture, for example inkjet printing or spin-coating.

A typical organic light-emissive device (“OLED”) is fabricated on a glass or plastic substrate coated with a transparent anode such as indium-tin-oxide (“ITO”). A layer of a thin film of at least one electroluminescent organic material covers the first electrode. In W090/13148 the organic light-emissive material is a conjugated polymer. In U.S. Pat. No. 4,539,507 the organic light-emissive material is of the class known as small molecule materials, such as (8-hydroxyquinoline) aluminium (“Alq3”). Finally, a cathode covers the layer of electroluminescent organic material.

In operation, holes are injected into the device through the anode and electrons are injected into the device through the cathode. The holes and electrons combine in the organic electroluminescent layer to form an exciton which then undergoes radiative decay to give light. Conversely, photovoltaic devices and photosensors are optoelectronic devices that may have essentially the same structure as an OLED but which operate by photoinduced charge separation.

OLEDs have great potential for display and lighting applications. However, there remains a need to increase the stability of these devices, in particular in multicolour and full colour devices (that is, devices comprising more than one organic light emitting material into which holes and electrons are injected).

The cathode of an OLED typically comprises metal or alloy and may comprise a single layer, such as aluminium, or a plurality of layers, for example a bilayer of a low workfunction material and a high workfunction material such as calcium and aluminium as disclosed in WO 98/10621 or elemental barium as disclosed in WO 98/57381, Appl. Phys. Lett. 2002, 81(4), 634 and WO 02/84759.

U.S. Pat. No. 6,576,093 discloses a bilayer cathode comprising a layer of a low workfunction material such as Ca and a layer of a higher workfunction material such as aluminium. It is described that a cathode layer is typically deposited by vacuum evaporation or by a sputtering technique such as rf sputtering or dc magnetron sputtering. It is described that when the underlying layer is a layer of a relatively sensitive material such as a soluble conjugated polymer, vacuum evaporation is often the preferred technique for depositing the first layer because it is a relatively low-energy process which causes less damage to the underlying layer of organic material. It is further described that cathode layers deposited by conventional vacuum evaporation techniques contain pinholes through which water and oxygen are able to enter the device and initiate reactions at the interface between the organic layer and the cathode. These reactions result in the formation of non-emitting black spots with a consequential degradation in device performance. Accordingly, it is suggested that the cathode should be formed by depositing a first layer of a low workfunction material using a low energy deposition technique such as vacuum evaporation and depositing a second layer of a higher workfunction material by a conformable deposition technique such as a sputtering technique.

A cathode comprising a bilayer of lithium fluoride and aluminium has been reported to improve device efficiency—see for example Appl. Phys. Lett. 70, 152, 1997. This improvement is believed to result from a reduction in the barrier height at the organic layer/cathode interface, allowing improved electron injection into the organic layer(s).

U.S. Pat. No. 5,739,635 discloses organic electroluminescent devices comprising a cathode made of a conductive material and an electron injecting layer selected from the group consisting of alkaline metal oxides, alkaline metal peroxides, alkaline metal compound oxides, alkaline metal halides, alkaline metal nitrides and alkaline metal salts.

The inventors have surprisingly found that the stability of an organic optoelectronic device may be increased by use of a layer comprising a complex salt.

Accordingly, in a first aspect the invention provides an organic optoelectronic device comprising an anode, a cathode and an active organic layer between the anode and the cathode, wherein the cathode comprises a layer comprising a complex salt, a first conductive layer, and a second conductive layer over the first conductive layer.

Optionally, the complex salt comprises a halogen, preferably fluorine.

Optionally, the complex salt is a metal hexafluoroaluminate.

Optionally, the complex salt comprises a metal cation.

Optionally, the layer comprising the complex salt is a composite layer.

Optionally, the composite layer comprises the complex salt and a metal halide or metal oxide.

Optionally, the layer comprising a complex salt is in contact with the active organic layer.

Optionally, at least one intervening layer is provided between the layer comprising a complex salt and the active organic layer. The at least one intervening layer may be a layer of a silicon oxide, preferably silicon monoxide, or silicon dioxide.

Optionally, the first conductive layer comprises a metal.

Optionally, the cathode is transparent.

Optionally, the organic optoelectronic device is an organic light-emitting device wherein the active organic layer is an organic light-emitting layer.

Optionally, the organic light-emitting device comprises red, green and blue organic light-emitting materials.

In a second aspect the invention provides a method of forming an organic optoelectronic device comprising the steps of: providing an anode; depositing a layer comprising an active organic material; depositing a layer comprising a complex salt; and depositing a first conductive layer.

Optionally, the layer comprising a complex salt is deposited by evaporation.

Optionally, the active organic material is deposited from a solution in a solvent.

“Complex salt” as used herein means a salt comprising a cation and an anion wherein the anion comprises a metal. Optionally, the anion comprises a metal complex. Optionally, there is substantially no detectable quantity of at least one of the metal ions of the complex salt in solution; taking K₃Fe(CN)₆ as an example, a solution of this complex salt will contain K⁺ ions but substantially no detectable quantity of Fe³⁺ because Fe is strongly bound to CN.

Particular embodiments of the invention will now be more fully described, by way of example, with reference to the drawings, of which:

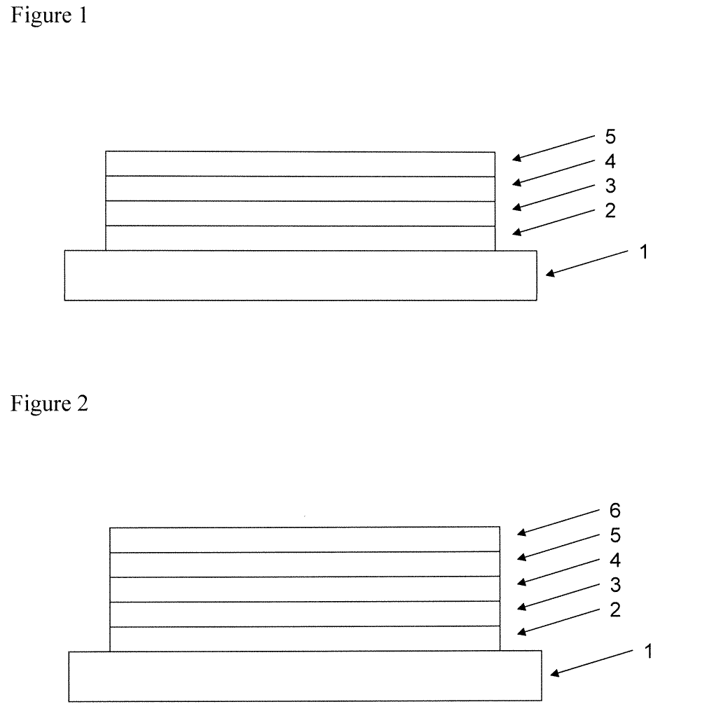

FIG. 1 illustrates a first embodiment of an electroluminescent device according to the invention.

FIG. 2 illustrates a second embodiment of an electroluminescent device according to the invention.

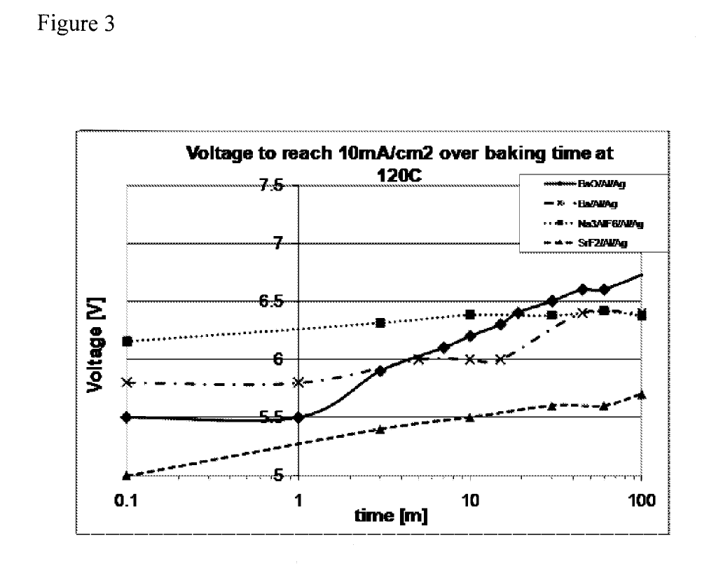

FIG. 3 is a comparative graph illustrating the drive voltages required over time to reach a current density of 10 mA/cm² for a device according to the invention and comparative devices.

With reference to FIG. 1, the architecture of an electroluminescent device according to the invention comprises a transparent glass or plastic substrate 1, an anode 2 and a cathode comprising an electron injecting layer 4 comprising a complex metal salt and a conductive layer 5. An electroluminescent layer 3 is provided between anode 2 and the cathode.

Exemplary complex salts are metal hexafluoroaluminates and ferricyanides, for example K₃Fe(CN)₆.

Preferred metal cations for these complex salts are alkali and alkali earth metal cations, in particular sodium, potassium, calcium and magnesium, preferably an alkali metal as in Na₃AlF₆ (cryolite).

The electron injecting layer may consist substantially of a single complex metal salt, or it may comprise further materials. For example, the electron injecting layer may be a composite layer formed by co-deposition of the complex metal salt with other materials such as metals, metal fluorides or metal oxides. It may also be a composite of more than one metal complex.

The electron injecting layer may have a thickness in the range of 0.3-10 nm, preferably 1-5 nm. A thickness below 0.5 nm is particularly preferred for magnesium.

The conductive layer 5 of this embodiment is preferably a high work function metal, in particular selected from metals with a workfunction of greater than 3.5 eV. Work functions of various metals are given in the CRC Handbook of Chemistry and Physics 2008, p. 12-114, published by CRC Press, edited by David R. Lide, and suitable metals with a work function above 3.5 eV include aluminium and silver.

In this embodiment, conductive layer 5 is the outer layer of the device. While it is beneficial for this outer layer to have a work function above 3.5 eV to reduce the susceptibility of the device to deterioration in the presence of moisture and oxygen, it is also desirable for this layer to be sufficiently reactive to cause rapid reduction of the metal complex salt in adjacent layer 4. Materials having a work function in the range of 3.5-4 eV are, for example magnesium, are therefore particularly beneficial for use in layer 5. However, materials having a work function below 3.5 eV may be used in conductive layer 5 of this embodiment, in particular in combination with a high work function layer 6.

The embodiment of FIG. 2 illustrates a device according to the invention corresponding to the device of FIG. 1 but with a second conductive layer 6.

Using only one conductive layer as per the embodiment of FIG. 1 can lead to degradation of the device, especially if the conductive layer is deposited by evaporation, which can leave pinholes in the layer, and if the device is not well encapsulated, thus allowing ingress of moisture and oxygen into the device via pinholes.

The problem of device degradation and non-uniform light emission caused by pin holes in the first conductive layer is solved by use of second conductive layer 6 without necessarily requiring the use of a high energy conformable deposition technique such as a sputtering technique as described in U.S. Pat. No. 6,576,093. Accordingly all layers of the cathode of the present invention may be deposited using a low energy deposition technique such as vacuum evaporation. It is postulated that the second conductive layer 6 fills in pinholes that may be present in layer 5, such that the layers 5 and 6 together form a smooth and relatively pinhole-free structure that is much more resistant to ingress of water and oxygen than the layer 5 alone.

Therefore, first conductive layer 5 may comprise a material having a work function above 3.5 eV such as aluminium, silver or magnesium, or it may comprise a material having a work function below 3.5 eV, such as calcium.

Second conductive layer 6 preferably comprises a material having a work function above 3.5 eV, for example aluminium or silver.

The first conductive layer and, where present, the second conductive layer may independently consist substantially of a single metal; an alloy such as aluminium and magnesium; or a composite of a metal with a compound or non-metallic element, such as a composite formed by co-deposition of a metal and a dielectric. Alloys are particularly preferred.

Preferably, the first and second conductive layers are formed in a vacuum chamber without any break in vacuum between deposition of these layers. In this way, the first and second conductive layers may provide the device with a “primary” encapsulation that protects the device from any exposure to moisture or oxygen that may occur before the device is provided with further encapsulating layers, in particular if they are both high work function layers.

In a practical device, at least one of the electrodes is semi-transparent in order that light may be emitted. Where the anode is transparent, it typically comprises indium tin oxide.

Transparent cathodes are particularly advantageous for active matrix devices because emission through a transparent anode in such devices is at least partially blocked by drive circuitry located underneath the emissive pixels.

It will be appreciated that a transparent cathode device need not have a transparent anode (unless, of course, a fully transparent device is desired), and so the transparent anode used for bottom-emitting devices may be replaced or supplemented with a layer of opaque or reflective material, for example a layer of metal such as aluminium, either above or below anode 2. Likewise, the substrate need not be transparent for such a “top-emitting” device. Examples of transparent cathode devices are disclosed in, for example, GB 2348316.

The embodiment of FIGS. 1 and 2 illustrate devices formed by firstly forming an anode on a substrate followed by deposition of an electroluminescent layer and a cathode, however it will be appreciated that the device of the invention could also be formed by firstly forming the cathode on a substrate followed by deposition of an electroluminescent layer and an anode.

Further layers may be located between anode 2 and the cathode, such as charge transporting, charge injecting or charge blocking layers as detailed below.

### Hole Injection Layers

It is particularly desirable to provide a conductive hole injection layer, which may be formed from a conductive organic or inorganic material provided between the anode 2 and the electroluminescent layer 3 to assist hole injection from the anode into the layer or layers of semiconducting polymer. Examples of doped organic hole injection materials include doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOₓMoOₓ and RuOₓ as disclosed in Journal of Physics D: Applied Physics (1996), 29(11), 2750-2753.

### Electroluminescent and Charge Transporting Layers

A hole transporting layer may be provided between the anode and the electroluminescent layer. Likewise, an electron transporting layer may be provided between the cathode and the electroluminescent layer.

If present, a hole transporting layer located between anode 2 and electroluminescent layer 3 preferably has a HOMO level of less than or equal to 5.5 eV, more preferably around 4.8-5.5 eV. HOMO levels may be measured by cyclic voltammetry, for example.

If present, an electron transporting layer located between electroluminescent layer 3 and cathode 4 preferably has a LUMO level of around 3-3.5 eV. In one embodiment, a layer of a silicon monoxide or silicon dioxide or other thin dielectric layer having a thickness in the range of 0.2-2 nm is provided between electroluminescent layer 3 and layer 4.

Electroluminescent layer 3 may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

Electroluminescent layer 3 may be patterned or unpatterned. A device comprising an unpatterned layer may be used an illumination source, for example. A white light emitting device is particularly suitable for this purpose. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Suitable materials for use in layer 3 include small molecule, polymeric and dendrimeric materials, and compositions thereof. Suitable electroluminescent polymers for use in layer 3 include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers for use in layer 3 include electroluminescent metal complexes bearing dendrimeric groups as disclosed in, for example, WO 02/066552.

Polymers for use as charge transporting and/or electroluminescent materials in devices according to the present invention preferably comprise a repeat unit selected from arylene repeat units as disclosed in, for example, Adv. Mater. 2000 12(23) 1737-1750 and references therein. Exemplary first repeat units include: 1,4-phenylene repeat units as disclosed in J. Appl. Phys. 1996, 79, 934; fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

Particularly preferred polymers comprise optionally substituted, 2,7-linked fluorenes, most preferably repeat units of formula IV:

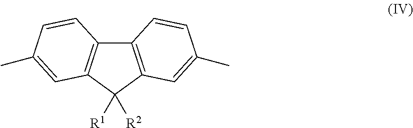

wherein R¹ and R² are independently selected from hydrogen or optionally substituted alkyl wherein one or more non-adjacent C atoms may be replaced with O, S, N, C═O and —COO—, alkoxy, aryl, arylalkyl, heteroaryl and heteroarylalkyl. More preferably, at least one of R¹ and R² comprises an optionally substituted C₄-C₂₀ alkyl or aryl group.

In the case where R is aryl or heteroaryl, preferred optional substituents include alkyl groups wherein one or more non-adjacent C atoms may be replaced with O, S, N, C═O and —COO—.

Optional substituents for the fluorene unit, other than substituents R¹ and R², are preferably selected from the group consisting of alkyl wherein one or more non-adjacent C atoms may be replaced with O, S, N, C═O and —COO—, optionally substituted aryl, optionally substituted heteroaryl, alkoxy, alkylthio, fluorine, cyano and arylalkyl.

Preferably, the polymer comprises an arylene repeat unit as described above and an arylamine repeat unit, in particular a repeat unit V:

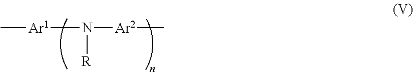

wherein Ar¹ and Ar² are optionally substituted aryl or heteroaryl groups, n is greater than or equal to 1, preferably 1 or 2, and R is H or a substituent, preferably a substituent. R is preferably alkyl or aryl or heteroaryl, most preferably aryl or heteroaryl. Any of the aryl or heteroaryl groups in the unit of formula 1 may be substituted. Preferred substituents include alkyl and alkoxy groups. Any of the aryl or heteroaryl groups in the repeat unit of Formula 1 may be be linked by a direct bond or a divalent linking atom or group. Preferred divalent linking atoms and groups include O, S; substituted N; and substituted C.

Particularly preferred units satisfying Formula 1 include units of

Formulae 1-3:

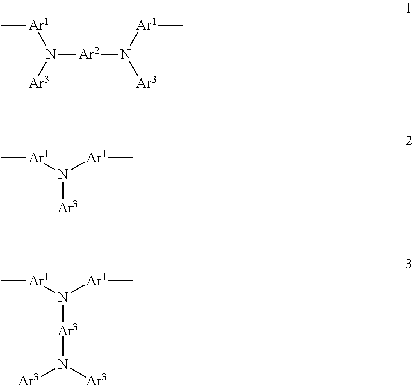

wherein Ar¹ and Ar² are as defined above; and Ar³ is optionally substituted aryl or heteroaryl. Where present, preferred substituents for Ar³ include alkyl and alkoxy groups.

Preferred concentration of the arylamine unit depends on the function of the polymer containing it. If the arylamine unit is present in a polymer for use in a hole transport layer it is preferably present in an amount up to 95 mol %, preferably up to 70 mol %. If the arylamine unit is present in a polymer for use in an emissive layer (as an emissive polymer or as the host for an emissive dopant) it is preferably present in an amount up to 30 mol %, preferably up to 20 mol %. These percentages apply to the total number of arylamine units present in the polymer in the case where more than one type of repeat unit of formula V is used.

The polymer may comprise heteroarylene repeat units for charge transport or emission.

Electroluminescent copolymers may comprise an electroluminescent region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality. Alternatively, an electroluminescent polymer may be blended with a hole transporting material and/or an electron transporting material. Polymers comprising one or more of a hole transporting repeat unit, electron transporting repeat unit and emissive repeat unit may provide said units in a polymer main-chain or polymer side-chain.

The different regions within such a polymer may be provided along the polymer backbone, as per U.S. Pat. No. 6,353,083, or as groups pendant from the polymer backbone as per WO 01/62869.

Polymers formed by the method of the present invention may be used in an electroluminescent device to provide one or more of the functions of hole transport, electron transport and emission depending on which layer of the device it is used in and the nature of co-repeat units.

A polymer formed by the method of the present invention may also be used as a host material for an emissive dopant that may be mixed with or bound to the polymer. In this case, the polymer should have a higher excited state energy level than that of the dopant. In the case of a phosphorescent dopant, the T₁ energy level of the polymer should be sufficiently high for excited state energy to be transferred from the T₁ energy level of the host to the T₁ level of the emitter. Preferably, the host has a T₁ energy level sufficiently high to prevent energy back-transfer from the T₁ energy level of the emitter, and in particular a T₁ energy level higher than that of the emitter. However, in some cases the T₁ energy level of the host may be the same, or even lower, than that of the emitter.

### Metal Complexes

Materials that may be used as fluorescent or phosphorescent dopants in the electroluminescent device include metal complexes comprising optionally substituted complexes of formula (VI):

ML¹_{q}L²ᵣL³ₛ (VI)

wherein M is a metal; each of L¹, L² and L³ is a coordinating group; q is an integer; r and s are each independently 0 or an integer; and the sum of (a.q)+(b.r)+(c.s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet or higher states (phosphorescence). Suitable heavy metals M include: lanthanide metals such as cerium, samarium, europium, terbium, dysprosium, thulium, erbium and neodymium; and d-block metals, in particular those in rows 2 and 3 i.e. elements 39 to 48 and 72 to 80, in particular ruthenium, rhodium, pallaidum, rhenium, osmium, iridium, platinum and gold.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals are particularly suitable for emission from triplet excited states. These metals form organometallic complexes with carbon or nitrogen donors such as porphyrin or bidentate ligands of formula (VII):

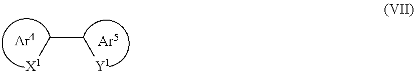

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

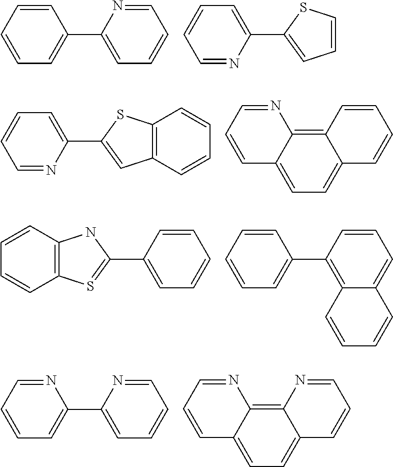

Each of Ar⁴ and Ar⁵ may carry one or more substituents. Two or more of these substituents may be linked to form a ring, for example an aromatic ring. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

A light-emitting dendrimer typically comprises a light-emitting core bound to one or more dendrons, wherein each dendron comprises a branching point and two or more dendritic branches. Preferably, the dendron is at least partially conjugated, and at least one of the core and dendritic branches comprises an aryl or heteroaryl group.

Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014]. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalinol-10-hydroxybenzo (h) quinolinato (II), benzazoles (III), schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission colour.

### Encapsulation

Optical devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is preferably encapsulated with an encapsulant (not shown) to prevent ingress of moisture and oxygen. Suitable encapsulants include a sheet of glass, films having suitable barrier properties such as silicon dioxide, silicon monoxide, silicon nitride, or alternating stacks of polymer and dielectric as disclosed in, for example, WO 01/81649 or an airtight container as disclosed in, for example, WO 01/19142. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Solution Processing

A single polymer or a plurality of polymers may be deposited from solution to form layer 3. Suitable solvents for polyarylenes, in particular polyfluorenes, include mono- or poly-alkylbenzenes such as toluene and xylene. Particularly preferred solution deposition techniques including printing and coating techniques, preferably spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, roll printing and screen printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

### EXAMPLE 1

A device having the following structure was formed:

ITO/HIL/HTL/EL/Na₃AlF₆/Al/Ag

(HIL represents a hole injection layer; HTL represents a hole transport layer; and EL represents an electroluminescent layer.)

The device was formed by spin-coating a layer of hole injection material, available from Plextronics, Inc. as Plextronics HIL 764, onto a layer of indium-tin oxide to a thickness of 60 nm.

A hole transport layer comprising fluorene units and amine units as described above was formed by spin-coating from xylene solution onto the layer of HIL to a thickness of 22 nm, and rendered insoluble by baking at 200° C. for 60 minutes.

A layer of electroluminescent material was formed by spin-coating a polymer comprising fluorene units and amine units as described above to a thickness of 60 nm.

A layer of Na₃AlF₆ was formed by thermal evaporation to a thickness of 2 nm, followed by evaporation of a layer of aluminium to a thickness of 200 nm and a layer of silver to a thickness of 100 nm.

Three comparative devices were formed as above, except that Na₃AlF₆ in these respective devices was replaced with BaO, elemental barium and strontium fluoride.

As can be seen from FIG. 3, the device according to the invention shows a much smaller increase over time in voltage required to reach a reference current density of 10 mA/cm² at a temperature of 120° C., indicating greater stability of this device.

The mechanism of operation of a cathode comprising a metal fluoride layer entails reduction of the metal fluoride to form the elemental metal and fluoride ions. The same mechanism operates in the case of a cathode according to the present invention, comprising a complex metal salt. Without wishing to be bound by any theory, the stability of the device according to the invention may be due to the larger size of the complex anion formed following reduction as compared to a fluoride ion, which makes it more difficult for the complex ion to migrate into the organic layers and cause quenching of emission.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic optoelectronic device comprising an anode, a cathode, and an active organic layer between the anode and the cathode, wherein the cathode comprises a layer comprising a complex salt, a first conductive layer, and a second conductive layer over the first conductive layer.

2. An organic optoelectronic device according to claim 1 wherein the complex salt comprises a halogen.

3. An organic optoelectronic device according to claim 1 wherein the complex salt is a metal hexafluoroaluminate.

4. An optoelectronic device according to claim 1 wherein the complex salt comprises a metal cation.

5. An organic optoelectronic device according to claim 1 wherein the layer comprising the complex salt is a composite layer.

6. An organic optoelectronic device according to claim 5 wherein the composite layer comprises the complex salt and a metal halide or metal oxide.

7. An organic optoelectronic device according to claim 1 wherein the layer comprising a complex salt is in contact with the active organic layer.

8. An organic optoelectronic device according to claim 1 wherein at least one intervening layer is provided between the layer comprising a complex salt and the active organic layer.

9. An organic optoelectronic device according to claim 8 wherein the at least one intervening layer is a layer of a silicon oxide.

10. An organic optoelectronic device according to claim 1 wherein the first conductive layer comprises a metal.

11. An organic light-emitting device according to claim 1 wherein the cathode is transparent.

12. An organic optoelectronic device according to claim 1 that is an organic light-emitting device wherein the active organic layer is an organic light-emitting layer.

13. An organic light-emitting device according to claim 12 comprising red, green, and blue organic light-emitting materials.

14. A method of forming an organic optoelectronic device comprising the steps of:
providing an anode;
depositing a layer comprising an active organic material;
depositing a layer comprising a complex salt; and
depositing a first conductive layer.

15. A method according to claim 14 comprising depositing the layer comprising a complex salt by evaporation.

16. A method according to claim 14 comprising depositing the active organic material from a solution in a solvent.

17. An organic optoelectronic device according to claim 2 wherein the complex salt comprises fluorine.

18. An organic optoelectronic device according to claim 9 wherein the at least one intervening layer is a layer of silicon monoxide or silicon dioxide.
